(19) United States
(12) Patent Application Publication
(10) Pub. No.: US 2006/0258115 A1
(43) Pub. Date: Nov. 16, 2006

(54) Semiconductor device and method of manufacturing the same

(75) Inventors: Takahito Nakajima, Yokkaichi (JP); Masahito Shinohe, Yokkaichi (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: Kabushiki Kaisha Toshiba, Minato-ku (JP)

(21) Appl. No.: 11/405,539

(22) Filed: Apr. 18, 2006

(30) Foreign Application Priority Data
Apr. 18, 2005 (JP) 2005-119691

(51) Int. Cl. H01L 21/76

(52) U.S. Cl. 438/424

(57) ABSTRACT

A method of manufacturing a semiconductor device includes forming a trench in a semiconductor substrate, forming a film containing impurities on an inner surface of a lower part of the trench, forming a silicon nitride film so that an upper sidewall of the trench is covered by the silicon nitride film, and diffusing the impurities outside the trench by heat treatment.

### CROSS-REFERENCE TO RELATED APPLICATIONS

This application is based upon and claims the benefit of priority from the prior Japanese Patent Application No. 2005-119691, filed on Apr. 18, 2005, the entire contents of which are incorporated herein by reference.

### BACKGROUND OF THE INVENTION

1. Field of the Invention

The present invention relates to a semiconductor device with a trench dynamic random access memory (DRAM) cell structure and a method of manufacturing the same.

2. Description of the Related Art

A degree of integration has recently been improved increasingly in semiconductor devices. A degree of improvement is noticeable particularly in semiconductor memory devices. A DRAM cell comprising one transistor and one capacitor is particularly required to be arranged so as to meet predetermined characteristics while a ratio of occupation of each major part to the whole cell is reduced. A conventional trench DRAM cell includes a capacitor formed under a trench. JP-A-2002-203950 discloses a technique of forming a film containing, for example, three or five value impurities in a lower inside of a trench and heat-treating the film so that the impurities are diffused into a semiconductor substrate outside the trench, whereby a plate electrode (a plate diffusion layer or capacitor electrode) is formed.

According to the above-described capacitor-forming technique, silica glass containing arsenic is deposited in a trench in order that a plate electrode of the capacitor may be formed. A tetraethyl orthosilicate (TEOS) film is further deposited on the deposited silica glass. Photoresist is then buried in the lower inside of the trench on the TEOS film so that the TEOS and silica glass formed on the photoresist are removed. Next, the photoresist and TEOS in the lower inside of the trench are removed and heat treatment is applied to the trench so that the arsenic is diffused outside the trench into the semiconductor substrate, whereby a plate electrode is formed.

In the above-described method, there is a possibility that impurities may scatter and adheres particularly to an upper part of the trench, resulting in adverse effects on the characteristics of the device. For the purpose of preventing the adverse effects, the silica glass formed on the upper sidewall of the trench needs to be removed and a TEOS film on the upper part of the trench.

However, the TEOS film needs to be formed at a high temperature (a range from 600° C. to 700° C. particularly in the case of arsenic). Accordingly, the forming of the TEOS film results in effects of heat treatment. As a result, the impurities scatter to parts of the semiconductor substrate which have adverse effects on the characteristics of the device when the TEOS film is formed.

### SUMMARY OF THE INVENTION

Therefore, an object of the present invention is to provide a semiconductor device which can suppress adherence of the impurities to portions of the semiconductor substrate other than a part outside the lower interior of the trench, and a method of manufacturing the same.

In one aspect, the invention provides a method of manufacturing a semiconductor device comprising forming a trench in a semiconductor substrate, forming a film containing impurities on an inner surface of a lower part of the trench, forming a silicon nitride film so that an upper sidewall of the trench is covered by the silicon nitride film, and diffusing the impurities outside the trench by heat treatment.

The invention also provides a method of manufacturing a semiconductor device comprising forming a trench in a semiconductor substrate, forming a silicon nitride film so that an upper sidewall of the trench is covered by the silicon nitride film, forming a film containing impurities on an inner surface of a lower part of the trench so that the silicon nitride film is covered by the impurities-containing film, and diffusing the impurities outside the trench by heat treatment.

In another aspect, the invention provides a semiconductor device comprising a semiconductor substrate formed with a trench, a capacitor insulating film formed on an inner surface of a lower interior of the trench, a conductive layer buried in an inside of the capacitor insulating film, and a silicon nitride film interposed between the trench and the capacitor insulating film and formed by a radical nitriding process.

### BRIEF DESCRIPTION OF THE DRAWINGS

Other objects, features and advantages of the present invention will become clear upon reviewing the following description of the embodiment with reference to the accompanying drawings, in which:

FIG. 1 is a schematic sectional view of the structure employed in a semiconductor device in accordance with one embodiment of the present invention, the figure being taken along line 1-1 in FIG. 2;

FIG. 2 is a schematic plan view of the memory cell region;

FIGS. 3 through 22 are longitudinal sections of the memory cell region in steps of a manufacturing process; and

FIG. 23 is a view similar to FIG. 8, showing a second embodiment of the invention.

### DETAILED DESCRIPTION OF THE INVENTION

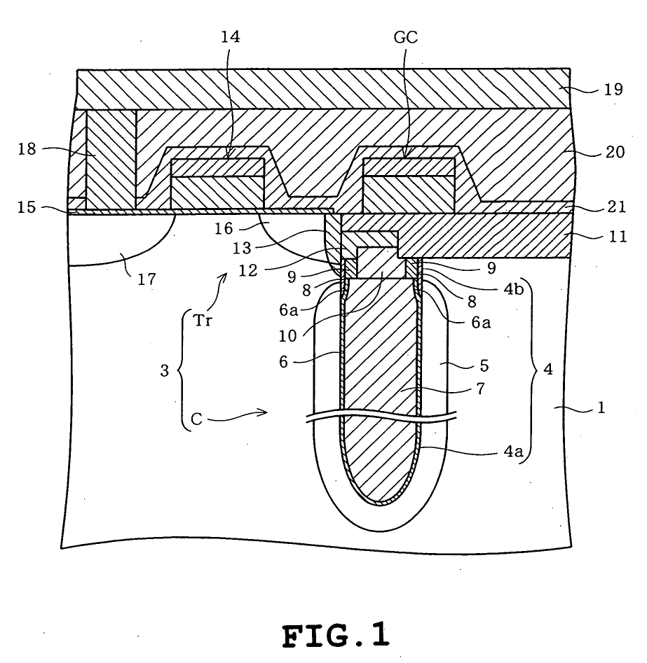

A first embodiment of the present invention will be described with reference to FIGS. 1 to 22.

### Structure

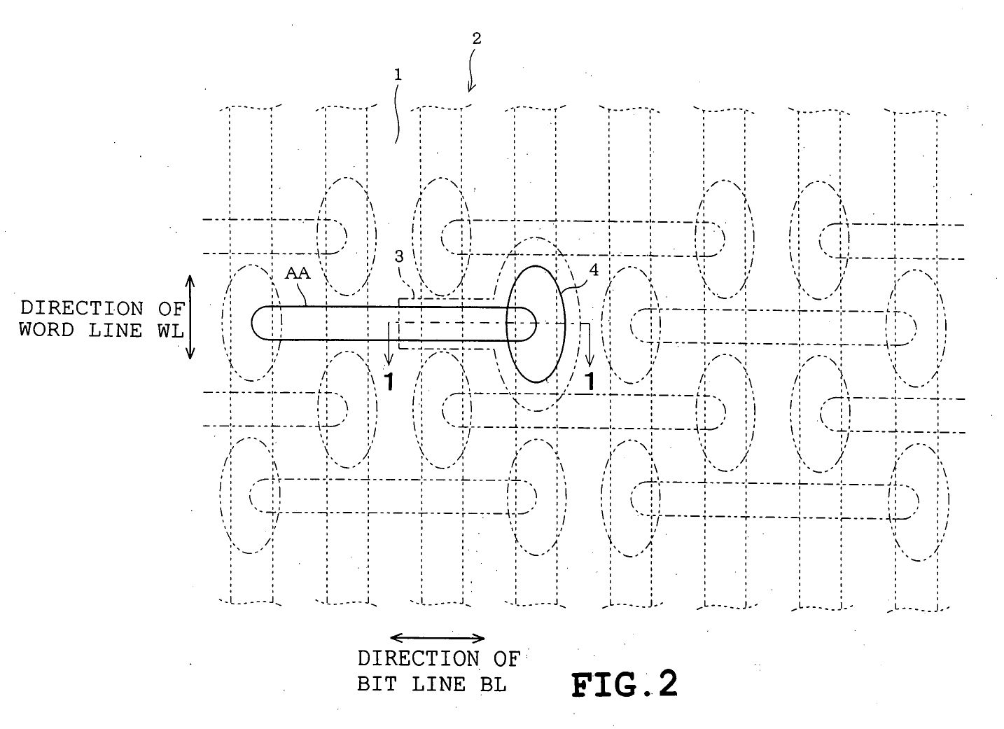

The structure of a characterized portion of the embodiment will be described with reference to FIGS. 1 and 2, which are longitudinal section and plan views a memory cell formed in a memory cell region of a trench DRAM as a semiconductor device. Although the DRAM cell is formed in a p-type silicon semiconductor substrate in the embodiment, the DRAM cell may be formed in a p-well region. Furthermore, another semiconductor substrate may be employed.

Referring to FIG. 2, an arrangement of memory cells constituting the DRAM is schematically shown. The trench-type DRAM 2 comprises a silicon semiconductor substrate 1 (serving as a semiconductor substrate) and a memory cell region in which a plurality of memory cells 3 are arranged. Reference symbol “AA” in FIG. 2 designates an active area of each memory cell 3. FIG. 1 is a longitudinal side section taken along line 1-1 in FIG. 2. As shown in FIG. 1, each memory cell 3 comprises one trench capacitor C and one cell transistor Tr.

The arrangement of the memory cell 3 will be described in detail. The silicon substrate 1 has a deep trench 4 formed in an upper part thereof. A trench capacitor C is formed in a lower interior 4a of the trench 4. A plate diffusion layer 5 is formed on an outer periphery of the trench 4. The plate diffusion layer 5 extends from the lower interior of the trench 4 (bottom) to a predetermined level. The plate diffusion layer 5 functions as a plate electrode of the trench capacitor C constituting the memory cell 3. A capacitor insulating film 6 is anisotropically formed on an inner wall of the plate diffusion layer 5 at the lower interior 4a side. The capacitor insulating film 6 is comprised of an SiN—SiO₂ film, Al₂O₃—SiO₂ or HfO₂—SiO₂ film. The capacitor insulating film 6 functions as a film for separation of both plate electrodes of the trench capacitor C. A first conductive layer 7 is formed inside the capacitor insulating film 6 in the interior of the trench 4. The first conductive layer 7 is made from polycrystalline silicon containing impurities, amorphous silicon containing impurities or polycide and serves as a plate electrode of the trench capacitor C.

The capacitor insulating film 6 includes an upper part 6a which is formed so as to be located at a predetermined depth of the trench 4. The upper part 6a of the film 6 has an end face which is co-planar with an upper surface of the first conductive layer 7. The upper part 6a of the film 6 is formed so as to be bent inward with respect to the trench 4. A silicon nitride film 8 is formed by the radical nitriding of the upper inner surface of the trench 4 so as to interpose between the upper part 6a and the inner surface of the trench 4. The silicon nitride film 8 is rendered thinner as it comes nearer to the lower interior 4a.

A sidewall insulating film 9 is formed along an inner peripheral surface of the silicon nitride film 8 so as to be located on the capacitor insulating film 6 and the first conductive layer 7. The sidewall insulating film 9 is thicker than at least the capacitor insulating film 6 for the purpose of suppression in leak current of a vertical parasitic transistor, thereby serving as a collar insulating film. A second conductive layer 10 is formed inside the sidewall insulating film 9. The second conductive layer 10 is made from polycrystalline silicon containing impurities, amorphous silicon containing impurities or polycide.

An element isolation insulating film 11 or, for example, a silicon oxide film is formed on a part of the second conductive layer 10. The element isolation insulating film 11 electrically insulates and isolates the conductive layers 7, 10 and 12 buried in the trench 4 from other memory cells (not shown). Furthermore, the element isolation insulating film 11 provides electrical insulation for a gate electrode GC passing over the film 11. Additionally, a third conductive layer 12 is formed on a side of the element isolation insulating film 11 and the second conductive layer 10. The third conductive layer 12 is made from polycrystalline silicon containing impurities, amorphous silicon containing impurities or polycide and serves as a buried strap.

A cell transistor Tr is formed at a predetermined side relative to a horizontal plane of the trench 4 so as to be in contact with the trench capacitor C. A strap 13 is formed on a part of an interface between the third conductive layer 11 buried in the trench 4 and the cell transistor Tr. Impurities are diffused outward through an interface between the third conductive layer 12 and the trench 4, so that the strap 13 is formed on a part (the side of the diffusion layer 16 constituting the cell transistor Tr) of outer periphery of the trench 4.

The cell transistor 8 comprises a gate insulating film 15 formed on an upper surface of the silicon substrate 1, a gate electrode 14 formed on the gate insulating film 15 and n-type diffusion layers 16 and 17 (source/drain region) formed at the surface layer side of the silicon substrate 1 so as to be located at opposite sides of the gate electrode 14. The diffusion layer 16 is connected to the third conductive layer 12 so as to be electrically conductive. Furthermore, a bit line 19 is connected via the contact plug 18 to the diffusion layer 17 so as to be electrically conductive. An interlayer insulating film 20 is made from silicon oxide film 20 so that the bit line 19 is electrically isolated from the transistor Tr and trench capacitor C. An insulating film 21 is formed so as to cover the gate electrode 14. The insulating film 21 is comprised of a silicon nitride film, for example.

Thus, the trench capacitor C includes the first to third conductive layers 7, 10 and 12, the plate diffusion layer 5 and the capacitor insulating film 6 all provided in the trench 4. The capacitor insulating film 6 is interposed between the conductive layers 7, 10 and 12 and the plate diffusion layer 5. Each one of the memory cells 3 is thus constituted. As shown in FIG. 2, the memory cells 3 are arranged zigzag, and the trenches 4 are formed into an elliptic columnar shape.

There has conventionally been a possibility that impurities may be discharged from the first conductive layer 7 buried in the trench 4 toward the upper interior 4b of the trench 4. When the impurities are discharged toward the upper interior 4b of the trench 4, the trench 4 cannot be maintained in an ordinary state.

According to the structure of the embodiment, the capacitor insulating film 6 is formed at the lower interior 4a side of the trench 4 so as to reach the predetermined depth of the silicon substrate 1. Furthermore, the silicon nitride film 8 is rendered thinner as it comes nearer to the lower interior 4a. The silicon nitride film 8 is further interposed between the inner surface of the trench 4 and the upper part 6a of the capacitor insulating film 6. Accordingly, an area of the upper part of the first conductive layer 7 can be rendered smaller as compared with an arrangement that no silicon nitride film 8 is interposed between the trench 4 and the capacitor insulating film 6. As a result, a passage through which the impurities in the first conductive layer 7 are discharged upward can be narrowed. Consequently, the impurities in the first conductive layer 7 can be maintained in the normal state, whereupon the memory cell 3 with high reliability can be formed.

### Manufacturing Process

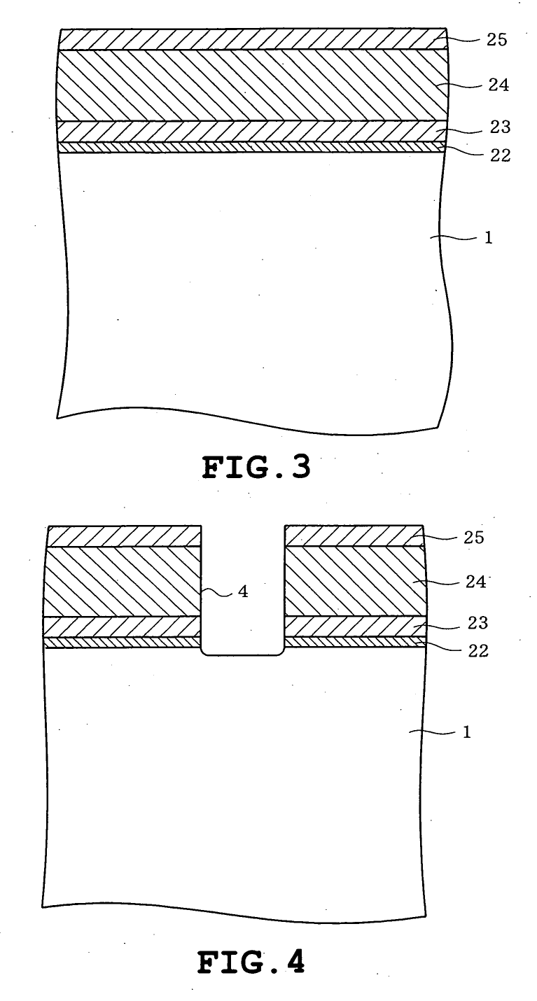

The manufacturing process of the trench-type DRAM 2 and more particularly of the memory cell 3 will now be described with reference to FIGS. 3 to 22. On condition that the manufacturing method in accordance with the invention can be realized, one or more of the steps which will be described later may be eliminated and/or one or more ordinary steps may be added.

FIGS. 3 through 22 show sequential steps of the manufacturing process of the memory cell 3. As shown in FIG. 3, the silicon oxide film 22 is formed on the silicon substrate 1, and the silicon nitride film 23 is formed on the silicon oxide film 22. A boron silicate glass (BSG) film 24 is deposited on the silicon nitride film 23. The TEOS film 25 is further deposited on the BSG film 24. As shown in FIG. 4, photoresist (not shown) is applied to the TEOS film 25 and then patterned for the forming of the trench 4. An anisotropic etching process is carried out to etch the silicon oxide film 22, the silicon nitride film 23, the BSG film 24 and the TEOS film 25 so that the trench 4 is formed. Thereafter, the resist pattern is removed.

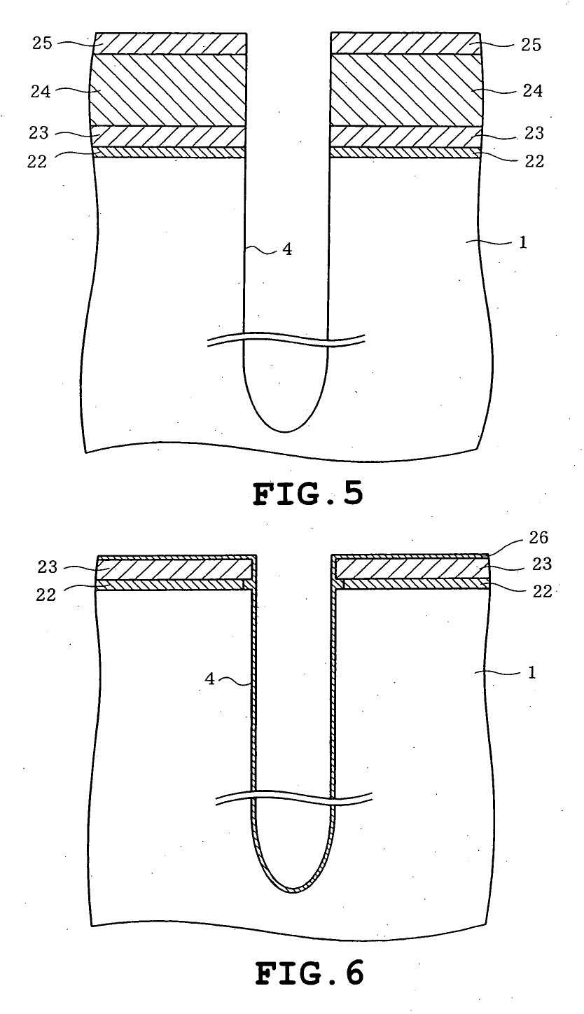

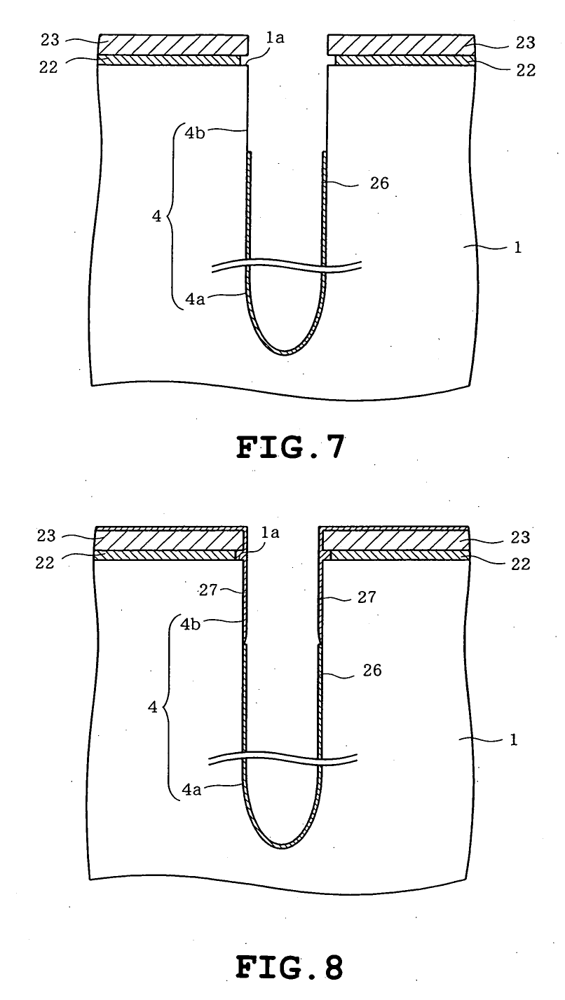

Subsequently, as shown in FIG. 5, the anisotropic etching process is carried out with the BSG and TEOS films 24 and 25 serving as a mask to process the silicon substrate 1 so that a predetermined depth is reached, whereby the deep trench 4 is formed. Thereafter, the BSG and TEOS films 24 and 25 are removed. Next, as shown in FIG. 6, silica glass 26 (AsSG film serving as a film containing impurities) doped with impurities (arsenic) is isotropically formed on the inner surface of the lower interior 4a of the trench 4. Thereafter, as shown in FIG. 7, resist (not shown) is applied and recessed by a chemical dry etching (CDE) process. Furthermore, the silica glass 26 formed on the upper part of the trench 4 is removed by a solution of buffered hydrofluoric acid (BHF).

Subsequently, the resist is removed by a chemical of sulfuric acid and hydrogen peroxide and thereafter, plasma nitriding (radical nitriding) is carried out under the condition of a constant low temperature in a range which is not less than 200° and less than 600° C. and under the condition of a constant pressure between minimum of 10 m Torr and maximum of 10 Torr, whereby the silicon nitride film 27 is formed so as to cover the sidewall of the upper interior 4b of the trench 4, as shown in FIG. 8. As a result, the thin silicon nitride film 27 can be formed so as to extend from the surface 1a side of the silicon substrate 1 toward the lower interior 4a. In this case, parameters of a film forming time, pressure, temperature and gas flow rate are adjusted, whereby a film thickness is adjusted. Consequently, the depth of the plate diffusion layer can be adjusted.

The density and film formation speed differ as the conditions of the plasma nitriding vary. Accordingly, it is difficult to determine one optimum condition for the plasma nitriding. However, the inventors conducted an experiment repeatedly and obtained the result that lower pressure can achieve better tendency.

In the embodiment, the radical nitriding is carried out under the conditions of the temperature of 400° C., pressure of 50 m Torr, N₂:40 sccm, Ar:1000 sccm and microwave power of 1000 W, so that the thin silicon nitride film 27 is formed so as to extend from the surface 1a side of the silicon substrate 1 toward the lower interior 4a. Symbol, sccm, is an abbreviation of standard cc/min. which is a unit of flow rate. After the silicon nitride film 27 has been formed, the film thickness of the silicon nitride film 27 can be reduced using H₃PO₄, HF/Gly or the like.

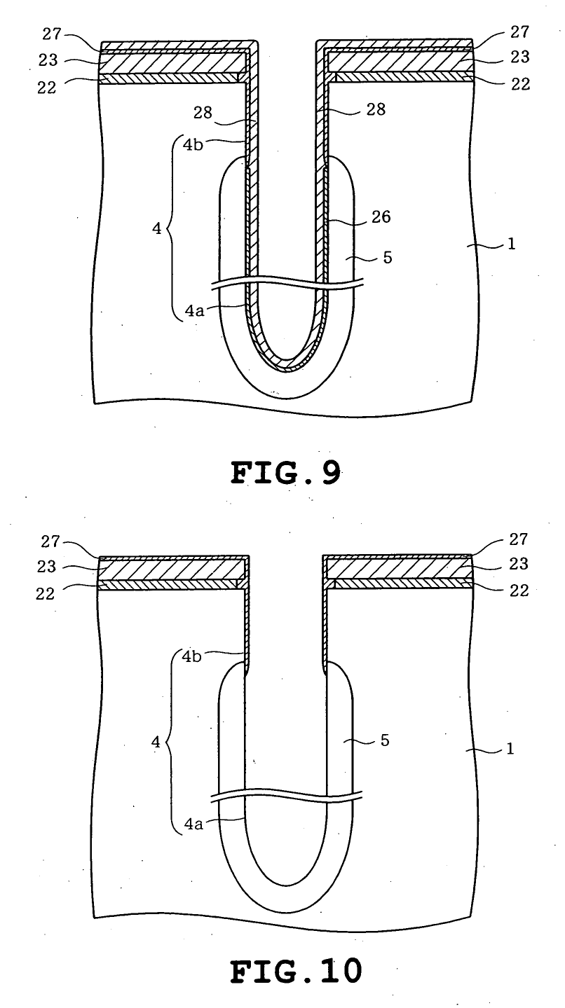

Subsequently, the cap TEOS film 28 is isotropically formed so as to cover the silica glass 26 and the silicon nitride film 27 as shown in FIG. 9. The TEOS film 28 is provided for the purpose of preventing arsenic from adhering from the silica glass 26 to the inside of the trench 4 and further preventing arsenic from scattering in the trench 4 (particularly, upward). The TEOS film 28 is formed at the temperature ranging from 600° C. to 700° C. Arsenic contained in the silica glass 26 sometimes rises in the trench 4. However, since the silicon nitride film 27 is formed on the upper part of the trench 4 before the forming of the TEOS film 28, arsenic is prevented from adhering to the inner surface of the trench 4. Consequently, the silicon substrate 1 can be prevented from contamination of arsenic therein and accordingly, the device characteristics of the cell transistor Tr formed so as to be in contact with the trench capacitor C can be stabilized. Subsequently, heat treatment is applied to the silicon substrate 1 so that arsenic is isotropically diffused, and the plate diffusion layer 5 of the trench capacitor C is formed around the trench 4.

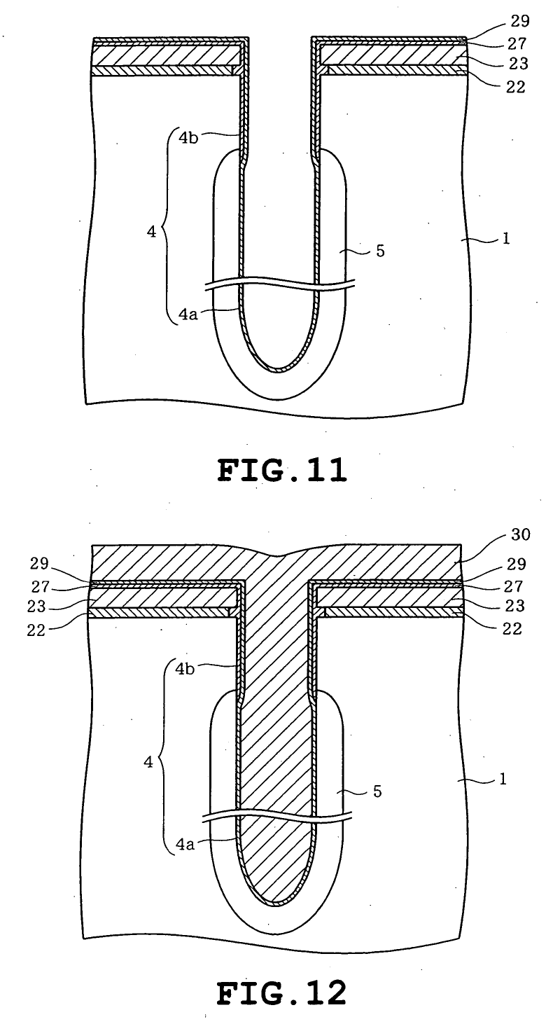

Subsequently, the TEOS film 28 and silica glass 26 both in the trench 4 are delaminated by a wet etching process as shown in FIG. 10. Next, as shown in FIG. 11, a insulating film 29 is isotropically formed on the inner surface of the trench 4. The insulating film 29 is comprised of an SiN—SiO₂ film, Al₂O₃—SiO₂ or HfO₂—SiO₂ film. Subsequently, as shown in FIG. 12, a conductive layer 30 is formed inside the insulating film 29 formed in the trench 4. The conductive layer 30 is made from polycrystalline silicon doped with impurities including arsenic, phosphor or the like, amorphous silicon doped with the similar impurities or polycide.

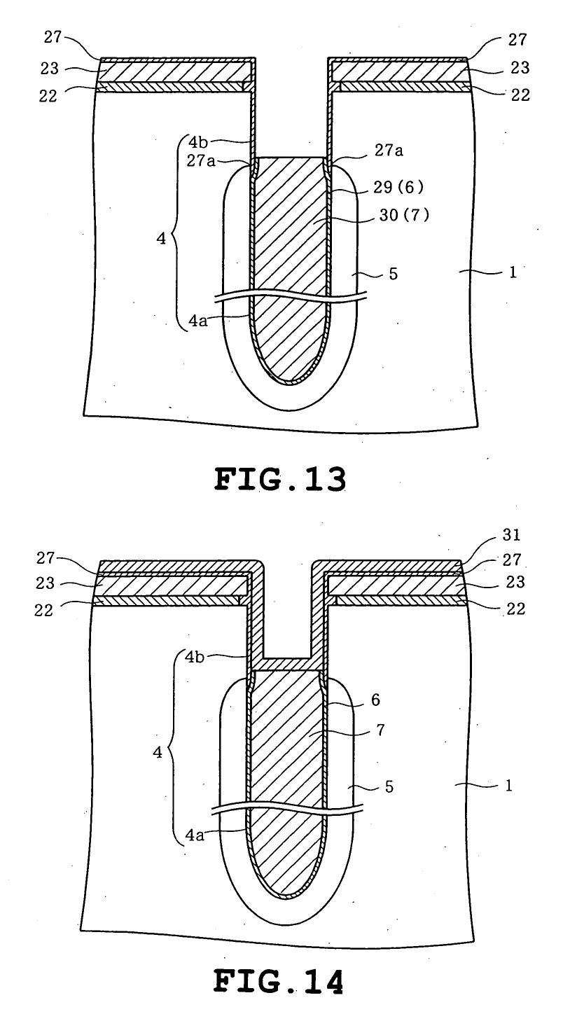

Subsequently, the conductive layer 30 and the insulating film 29 both formed in the upper interior 4b of the trench 4 are etched thereby to be removed, as shown in FIG. 13. In this case, parts of the conductive layer 30 and the insulating film 29 remain unremoved so as to cover the interior of the trench 4 located lower than the lower end 27a of the silicon nitride film 27. As a result, the upper surfaces of the first conductive layer 7 and the capacitor insulating film 6 can be co-planar, and the first conductive layer 7 and the capacitor insulating film 6 can be formed at the lower interior 4a side of the trench 4.

Subsequently, the insulating film 31 is isotropically formed on the silicon nitride film 27, the upper surface of the conductive layer 7 and the capacitor insulating film 29 by a low pressure chemical vapor deposition (LP-CVD) process, as shown in FIG. 14. The insulating film 31 is comprised of a silicon oxide film and is formed so as to be thicker than the capacitor insulating film 6 which is formed on the inner surface of the trench 4 at the lower interior 4a side.

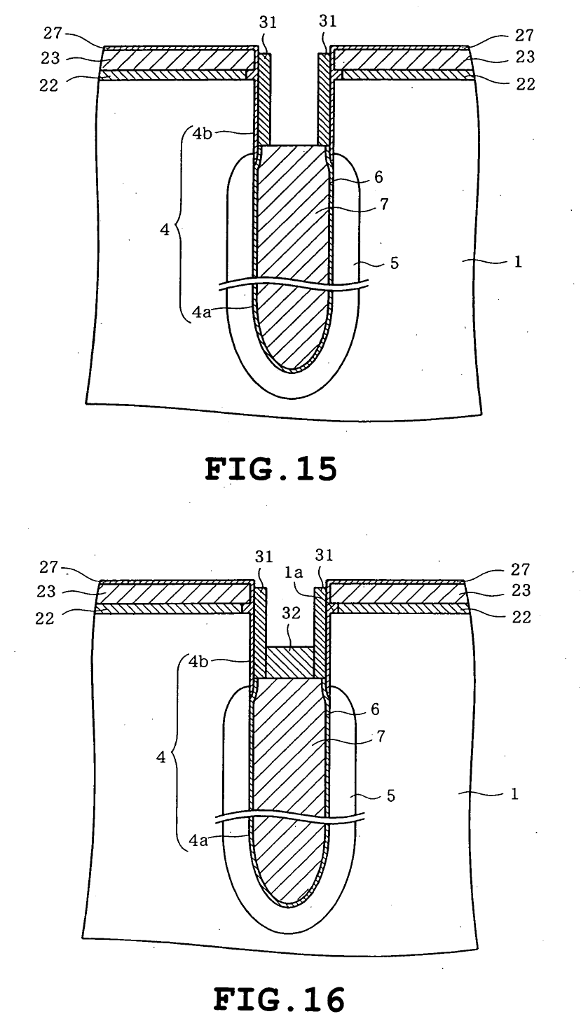

Subsequently, the insulating film 31 is removed by the reactive ion etching (RIE) process as shown in FIG. 15. As a result, a part of the insulating film 31 formed on the upper surface of the conductive layer 7 is removed and another part of the insulating film 31 located higher than the upper surface of the silicon substrate 1 is also removed.

Subsequently, the conductive layer 32 is buried in the trench 4 so as to be in contact with the upper surface of the first conductive layer 7 such that the conductive layer 32 is electrically conductively connected to the first conductive layer 7, as shown in FIG. 16. The conductive layer 32 is made from polycrystalline silicon doped with donor impurities, amorphous silicon doped with donor impurities or polycide, for example. The conductive layer 32 is then etched so that an upper surface thereof is located near the upper surface 1a of the silicon substrate 1.

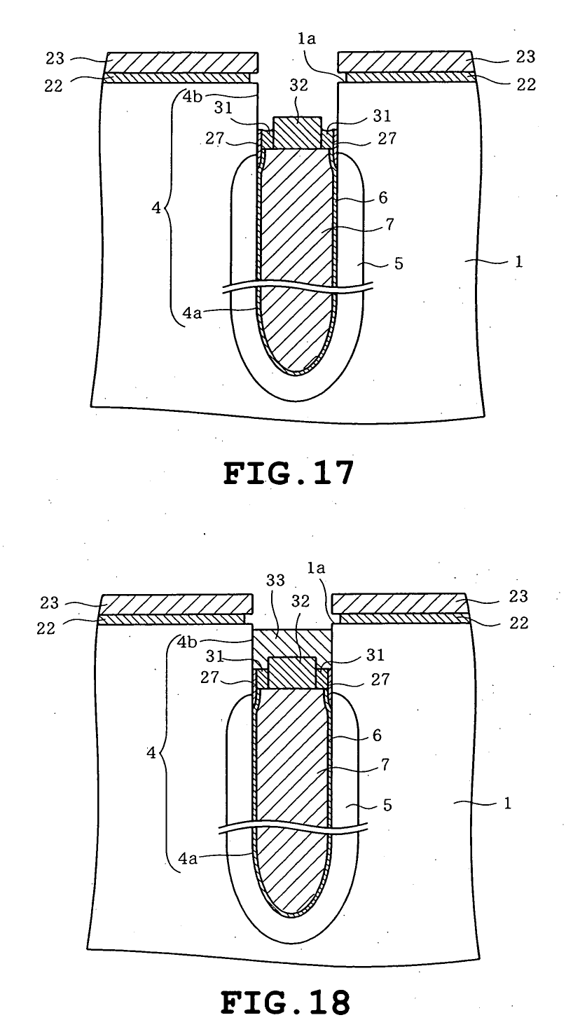

Subsequently, upper parts of the insulating film 31 and the silicon nitride film 27 are processed by a selective isotropic etching so that upper surfaces of the insulating film 31 and the silicon nitride film 27 are located slightly deeper than the upper surface of the conductive layer 32, as shown in FIG. 17. More specifically, the upper parts of the insulating film 31 and the silicon nitride film 27 are removed so that the upper surfaces of the insulating film 31 and the silicon nitride film 27 are located lower than the upper surface of the conductive layer 32 and upper than the upper surface of the first conductive layer 7.

Subsequently, a conductive layer 33 is buried in the trench 4 and then etched so that an upper surface thereof is located near the upper surface 1a of the silicon substrate 1, as shown in FIG. 18. The conductive layer 33 is made from polycrystalline silicon doped with impurities such as arsenic, phosphor or the like, amorphous silicon doped with impurities or polycide, for example. As shown in FIG. 18, the conductive layer 33 is buried in the trench 4 so as to be located over the conductive layer 32, the insulating film 31 and the silicon nitride film 27.

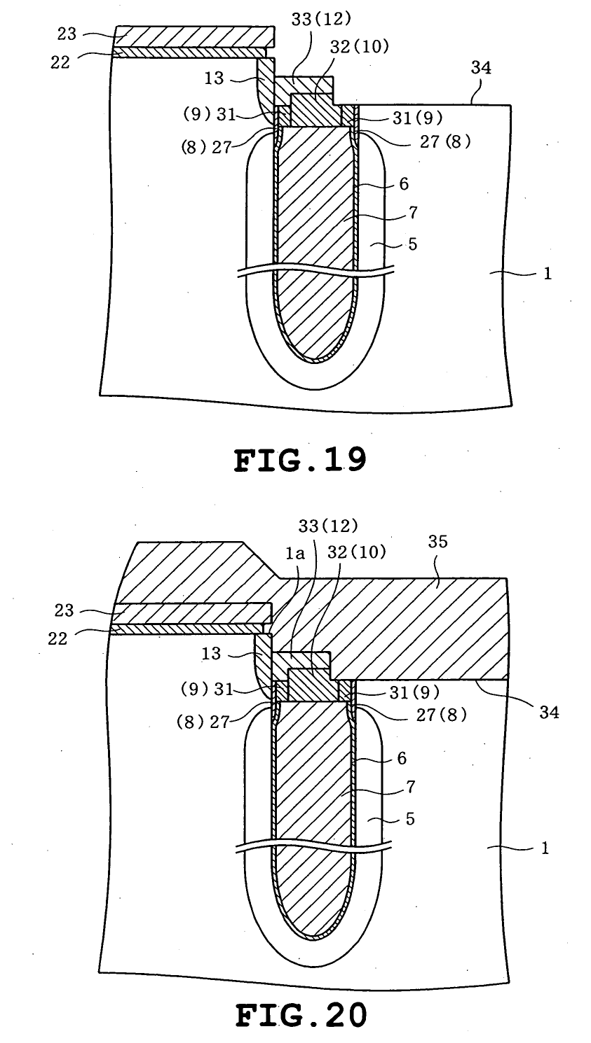

Subsequently, a heat treatment is carried out so that impurities are diffused from the conductive layer 33 into a part of the silicon substrate 1 located around the upper interior 4b of the trench 4, whereby a strap 13 is formed, as shown in FIG. 19. The strap 13 serves to suppress electrical resistance between the diffusion layer 16 constituting the cell transistor Tr and the trench capacitor C. Next, a trench 34 for forming an element isolation region is formed at one side of the trench 4. The trench 34 is located at opposite side of the formation region of the transistor Tr which is paired with the trench capacitor C with respect to the horizontal direction.

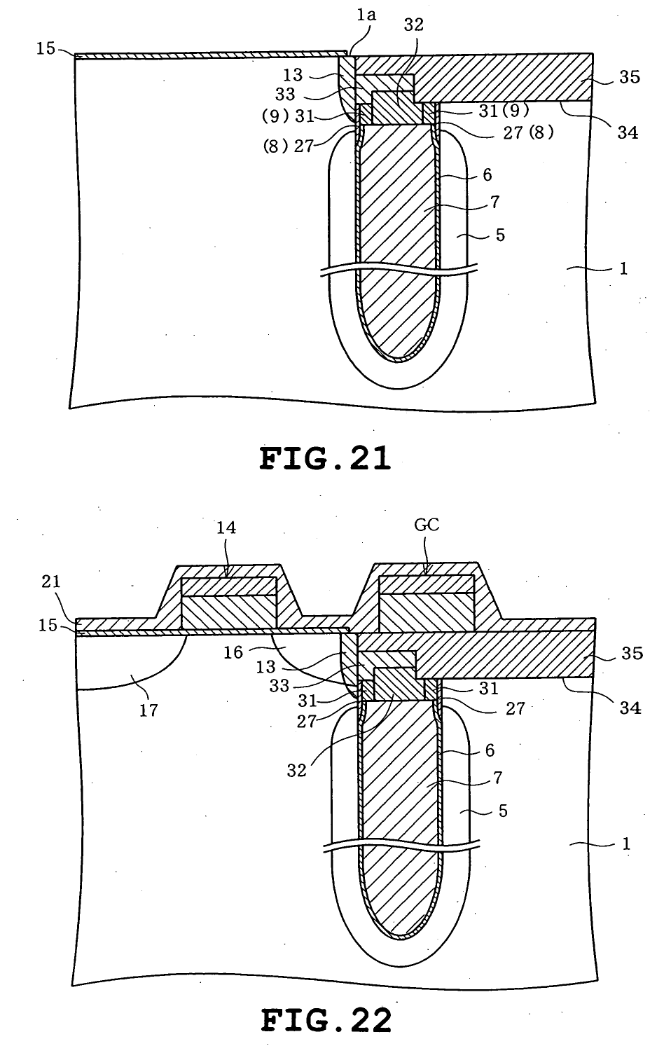

Subsequently, an element isolation insulating film 35 is buried in the trench 34 as shown in FIG. 20. The element isolation insulating film 35 is comprised of a silicon oxide film, for example. Next, as shown in FIG. 21, the element isolation insulating film 35 is then etched so that an upper surface thereof is located near the upper surface 1a of the silicon substrate 1, as shown in FIG. 21. As a result, the element isolation insulating film 35 is formed at the side of and over the conductive layer 33. Next, the silicon oxide film 22 and the silicon nitride film 23 are delaminated, and the gate insulating film 15 is formed on the upper surface 1a of the silicon substrate 1.

Subsequently, the gate electrode 14 is formed on the gate insulating film 15, and the diffusion layers 16 and 17 serving as source/drain regions are formed, as shown in FIG. 22. Additionally, the gate electrode GC is formed on the element isolation insulating film 35. Next, the insulating film 21 is formed so as to cover the gate electrodes 14 and GC. The insulating film 21 functions as a gate side insulating film. Next, as shown in FIG. 1, the interlayer insulating film 20, the contact plug 18 and the bit line 19 are sequentially formed. Thus, the memory cell 3 provided with the cell transistor Tr and the trench capacitor C is manufactured.

The insulating film 31 is composed into a sidewall insulating film 9 through the above-described manufacturing process, and the silicon nitride film 27 is composed into a silicon nitride film 8. Furthermore, the conductive layer 32 is composed into the second conductive layer 33, and the conductive layer 32 is composed into the third conductive layer 12. The element isolation insulating film 35 is composed so as to correspond to the element isolation insulating film 11.

The above-described manufacturing method has the following characteristics. A deep trench 4 is formed in the silicon substrate 1. The silica glass 26 is isotropically formed over the inner surface of the trench 4. The silica glass 26 formed on the sidewall defining the upper interior 4b of the trench 4 is removed while the silica glass 26 remains on the inner surface defining the lower the lower interior 4a of the trench 4. The silicon nitride film 27 is formed so as to cover the sidewall defining the upper interior 4b of the trench 4. The TEOS film 28 for forming the cap is isotropically formed in the trench 4 so as to cover the silica glass 26 and the silicon nitride film 27. The arsenic (impurity) is diffused around the trench 4 at the lower side 4a, whereby the plate diffusion layer 5 is formed. In this case, the silicon nitride film 27 is formed on the sidewall defining the upper interior 4b of the trench 4, and the TEOS film 28 is formed so as to cover the silica glass 26 and the silicon nitride film 27. Accordingly, even if high heat processing is carried out when the TEOS film 28 is diffused or when the impurities are diffused from silica glass 26 to the silicon substrate 1, arsenic can be prevented from adhering to the sidewall defining the upper interior 4b of the trench 4. Consequently, since the adherence of arsenic is suppressed in the part other than the lower interior 4a side of the trench 4, adverse effects on the characteristics of the cell transistor Tr can be suppressed.

The silica glass 26 is formed at the lower interior 4a side of the trench 4 and arsenic is diffused around the trench 4. Subsequently, when the silicon nitride film 27 is thinned or delaminated completely, adverse effects of the silicon nitride film 27 on the device characteristics can be avoided.

Since the silicon nitride film 23 is formed by plasma nitriding or radical nitriding, the silicon nitride film 23 can be formed only on the sidewall defining the upper interior 4b side of the trench 4 under the condition of low temperature (preferably, constant temperature in a range which is not less than 200° and less than 600° C., particularly 400° C.). Accordingly, even if the silica glass 26 is formed on the inner surface of the trench 4, arsenic contained in the silica glass 26 is not prevented from adhering to the inner surface of the trench 4. Consequently, the device characteristics can be maintained at normal values.

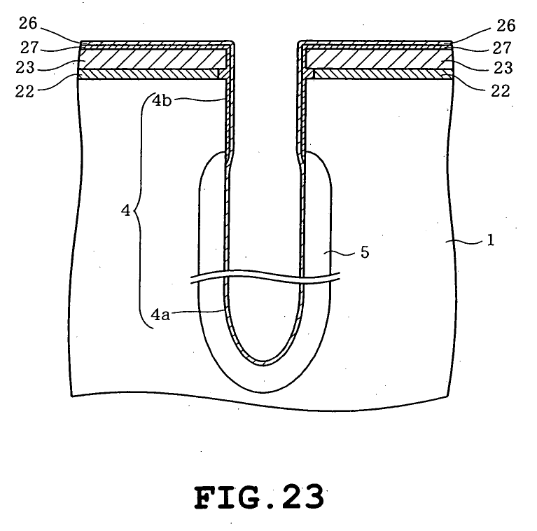

FIG. 23 illustrates a second embodiment of the invention. The second embodiment differs from the first embodiment in that after the radical nitriding has been carried out for the upper sidewall of the trench so that the silicon nitride film is formed, an AsSG film is formed so as to cover the silicon nitride film. Identical or similar parts in the second embodiment are labeled by the same reference symbols as those in the first embodiment. On the differences between the first and second embodiments will be described.

As described above with reference to FIG. 5 in the first embodiment, the plate diffusion layer 5 is formed through the following process after formation of the deep trench 4. The radical nitriding (or plasma nitriding) is carried out for the sidewall defining the upper interior 4b of the trench 4, whereby the silicon nitride film 27 is formed, as shown in FIG. 23. Thereafter, the silica glass 26 is isotropically formed in the trench 4 so as to cover the silicon nitride film 27. In this case, since the radical nitriding does not reach the lower interior 4a of the trench 4, the nitriding occurs only in the upper interior 4b of the trench 4.

Subsequently, a heat treatment is carried out so that arsenic is diffused from the silica glass 26 around the trench 4. As a result, the plate diffusion layer 5 is formed. In this case, the silicon nitride film 27 is formed on the inner surface of the sidewall defining the upper interior 4b of the trench 4. Accordingly, even if the silica glass 26 is formed inside the silicon nitride film 27, arsenic (impurities) can be prevented from diffusing to the region around the upper interior 4b of the trench 4. In particular, the device characteristics of the cell transistor Tr can be maintained in a normal state. The other steps in the manufacturing process are the same as those in the first embodiment, and accordingly, the same effect can be achieved from the second embodiment as from the first embodiment.

The invention should not be limited by the foregoing embodiments. The embodiments may be modified or expanded as follows. In the first embodiment, arsenic (impurities) is diffused around the trench 4 after the TEOS film 28 has been formed in the trench 4. However, the TEOS film 28 may or may not be formed. In other words, the TEOS film 28 may not be formed if the silicon nitride film 27 is formed on the sidewall defining the upper interior 4b of the trench 4.

In the foregoing embodiments, arsenic is diffused around the trench 4 and the plate diffusion layer 5 is formed. Thereafter, the insulating film 29 for serving as the capacitor insulating film 6 is formed while the silicon nitride film remains unremoved. However, the silicon nitride film 27 may be thinned or completely delaminated before the forming of the insulation film 29. In this case, since the silicon nitride film 27 does not remain on the inner surface of the trench 4, the reliability of the semiconductor device can be improved.

Although the conductive layer 32 is buried and then etched thereby to be formed into the second conductive layer 10, resist (not shown) may be applied, instead of the conductive layer 32. More specifically, after the structure as shown in FIG. 15 has been formed, resist may be applied to the silicon nitride film 27 and part of the resist over the trench 4 may cause to fall thereinto. Furthermore, the insulating film 31 serving as the sidewall insulating film 9 is removed by a wet etching process, and the silicon nitride film 27 may be removed. In this case, the step of burying the conductive layer needs to be carried out only twice, whereupon cost reduction can be achieved.

In FIGS. 16 and 17, the insulating film 31 may be damaged by implantation before being removed by an isotropic etching.

Arsenic is diffused from the silica glass 26 onto the silicon substrate 1 when the plate electrode 5 is formed as an electrode of the trench capacitor C. However, a film containing impurities including pentavalent impurity atoms such as phosphor (P) may be formed at the lower interior 4a side of the trench 4 and diffused. Furthermore, when the silicon substrate 1 has different conductivity types, a film containing impurities including trivalent impurity such as boron (B) may be formed at the lower interior 4a side of the trench 4 and diffused.

The foregoing description and drawings are merely illustrative of the principles of the present invention and are not to be construed in a limiting sense. Various changes and modifications will become apparent to those of ordinary skill in the art. All such changes and modifications are seen to fall within the scope of the invention as defined by the appended claims.

What is claimed is:

1. A method of manufacturing a semiconductor device comprising:
forming a trench in a semiconductor substrate;
forming a film containing impurities on an inner surface of a lower part of the trench;
forming a silicon nitride film so that an upper sidewall of the trench is covered by the silicon nitride film; and
diffusing the impurities outside the trench by heat treatment.

2. A method of manufacturing a semiconductor device comprising:
forming a trench in a semiconductor substrate;
forming a silicon nitride film so that an upper sidewall of the trench is covered by the silicon nitride film;
forming a film containing impurities on an inner surface of a lower part of the trench so that the silicon nitride film is covered by the impurities-containing film; and
diffusing the impurities outside the trench by heat treatment.

3. The method according to claim 1, wherein in the impurities containing film forming step, a part of the impurities-containing film formed on the upper sidewall of the trench is removed while another part of the impurities-containing film formed on the lower side of the trench remains, after the impurities-containing film has been formed on the inner surface of the trench.

4. The method according to claim 1, wherein the silicon nitride film is thinned or the whole silicon nitride film is exfoliated after the impurities have been diffused outside the trench.

5. The method according to claim 2, wherein the silicon nitride film is thinned or the whole silicon nitride film is exfoliated after the impurities have been diffused outside the trench.

6. The method according to claim 3, wherein the silicon nitride film is thinned or the whole silicon nitride film is exfoliated after the impurities have been diffused outside the trench.

7. The method according to claim 1, wherein a plasma nitriding process or a radical nitriding process is carried out so that the silicon nitride film is formed.

8. The method according to claim 2, wherein a plasma nitriding process or a radical nitriding process is carried out so that the silicon nitride film is formed.

9. The method according to claim 3, wherein a plasma nitriding process or a radical nitriding process is carried out so that the silicon nitride film is formed.

10. The method according to claim 4, wherein a plasma nitriding process or a radical nitriding process is carried out so that the silicon nitride film is formed.

11. The method according to claim 1, wherein the silicon nitride film is continuously formed so as to extend from an upper surface side of the semiconductor substrate toward the lower part of the trench.

12. The method according to claim 2, wherein the silicon nitride film is continuously formed so as to extend from an upper surface side of the semiconductor substrate toward the lower part of the trench.

13. The method according to claim 3, wherein the silicon nitride film is continuously formed so as to extend from an upper surface side of the semiconductor substrate toward the lower part of the trench.

14. The method according to claim 7, wherein the silicon nitride film is continuously formed so as to extend from an upper surface side of the semiconductor substrate toward the lower part of the trench.

15. The method according to claim 8, wherein the silicon nitride film is continuously formed so as to extend from an upper surface side of the semiconductor substrate toward the lower part of the trench.

16. The method according to claim 9, wherein the silicon nitride film is continuously formed so as to extend from an upper surface side of the semiconductor substrate toward the lower part of the trench.

17. The method according to claim 10, wherein the silicon nitride film is continuously formed so as to extend from an upper surface side of the semiconductor substrate toward the lower part of the trench.

18. The method according to claim 7, wherein in the step of forming the silicon nitride film, the silicon nitride film is formed at a constant temperature belonging to a range which is not less than 200° and less than 600° C.

19. The method according to claim 8, wherein in the step of forming the silicon nitride film, the silicon nitride film is formed at a constant temperature belonging to a range which is not less than 200° and less than 600° C.

20. A semiconductor device comprising:
a semiconductor substrate formed with a trench;
a capacitor insulating film formed on an inner surface of a lower interior of the trench;
a conductive layer buried in an inside of the capacitor insulating film; and
a silicon nitride film interposed between the trench and the capacitor insulating film and formed by a radical nitriding process.
